(19) United States
(12) Patent Application Publication
(10) Pub. No.: US 2016/0247981 A1
(43) Pub. Date: Aug. 25, 2016

(54) DISPLAY DEVICE AND MANUFACTURING METHOD OF THE SAME

(71) Applicant: Innolux Corporation, Chu-Nan (TW)

(72) Inventors: Yi-Xin YANG, Chu-Nan (TW); Cheng-Hsu CHOU, Chu-Nan (TW)

(73) Assignee: Innolux Corporation, Chu-Nan (TW)

(21) Appl. No.: 15/012,819

(22) Filed: Feb. 1, 2016

(30) Foreign Application Priority Data
Feb. 25, 2015 (TW) 104106026

(51) Int. Cl. H01L 33/54; G02F 1/1333; G02F 1/1339; H01L 51/52; H01L 51/56

(52) U.S. Cl. CPC H01L 33/54; H01L 51/5253; H01L 51/5259; H01L 51/56; G02F 1/1339; G02F 1/133305

(57) ABSTRACT

A display device and a manufacturing method of the same are provided. The display device includes a first substrate, a second substrate, a display element, an encapsulation layer, and an etching stop layer. The display element is located between the first substrate and the second substrate. The encapsulation layer surrounds the display element and contacts the first substrate and the second substrate. The etching stop layer surrounds the encapsulation layer and contacts the first substrate and the second substrate.

This application claims the benefit of Taiwan application Serial No. 104106026, filed Feb. 25, 2015, the subject matter of which is incorporated herein by reference.

### BACKGROUND OF THE INVENTION

1. Field of the Invention

The present disclosure is related in general to a display device and a manufacturing method thereof, and particularly to a display device having excellent durability and stability and a manufacturing method thereof.

2. Description of the Related Art

In the mass production of display devices, display elements are usually disposed on a mother board, and after components are assembled, a cutting process is performed on the mother board for manufacturing the display devices. In the cutting process by cutting knives, cracks may occur and remain on where the cutting process is performed, and such cracks may cause instability issue of the structures of the display devices.

In order to solve this issue, the industry has applied chemical etching processes on the cutting processes. However, cutting processes performed by chemical etching processes may raise other different issues, resulting in poor stability or short lives of the display devices.

### SUMMARY OF THE INVENTION

The present disclosure is directed to a display device and a manufacturing method thereof. In the embodiments, the etching stop layer surrounds the encapsulation layer and contacts the first substrate and the second substrate, such that the encapsulation layer can be effectively protected from the damage of the chemical etching solution in the manufacturing process, the encapsulation layer can achieve the effect of excellent resistance to water and oxygen, and the life of the display device can be further extended.

According to an embodiment of the present disclosure, a display device is provided. The display device includes a first substrate, a second substrate, a display element, an encapsulation layer, and an etching stop layer. The display element is located between the first substrate and the second substrate. The encapsulation layer surrounds the display element and contacts the first substrate and the second substrate. The etching stop layer surrounds the encapsulation layer and contacts the first substrate and the second substrate. The etching stop layer has at least a sidewall having an arc-shaped protruded surface.

According to another embodiment of the present disclosure, a manufacturing method of a display device is provided. The manufacturing method includes the following steps: providing a first base; disposing a plurality of display elements on the first base; disposing a plurality of encapsulation layers on the first base, each of the encapsulation layers surrounding each of the display elements; disposing a plurality of etching stop layers on the first base, wherein each of the etching stop layers surrounds each of the encapsulation layers, and the etching stop layers are separated from each other by a plurality of gaps; providing a second base to be assembled to the first base, wherein the encapsulation layers and the etching stop layers contact the first base and the second base; and performing a chemical etching process on the first base and the second base along the gaps between the etching stop layers for forming a plurality of the display devices separated from each other, wherein each of the display devices comprises one of the display elements, one of the encapsulation layers, and one of the etching stop layers.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1A shows a top view of a display device according to an embodiment of the present disclosure;

FIG. 1B shows a cross-sectional view along the section line 1B-1B′ in FIG. 1A;

FIG. 1C shows a cross-sectional view of a display device according to another embodiment of the present disclosure;

FIG. 1D shows a cross-sectional view of a display device according to a further embodiment of the present disclosure;

FIGS. 2A-2D illustrate a manufacturing method of a display device according to an embodiment of the present disclosure;

FIGS. 3A-3D illustrate a manufacturing method of a display device according to another embodiment of the present disclosure;

FIGS. 4A-4D illustrate a manufacturing method of a display device according to a further embodiment of the present disclosure; and

FIGS. 5A-5C illustrate a manufacturing method of a display device according to a still further embodiment of the present disclosure.

### DETAILED DESCRIPTION OF THE INVENTION

According to the embodiments of the present disclosure, a display device and a manufacturing method thereof are provided. In the embodiments, the etching stop layer surrounds the encapsulation layer and contacts the first substrate and the second substrate, such that the encapsulation layer can be effectively protected from the damage of the chemical etching solution in the manufacturing process, the encapsulation layer can achieve the effect of excellent resistance to water and oxygen, and the life of the display device can be further extended. The embodiments are described in details with reference to the accompanying drawings. However, the embodiments are for exemplification only, not for limiting the scope of protection of the disclosure. Besides, some of the secondary elements are omitted in the drawings accompanying the following embodiments to highlight the technical features of the invention.

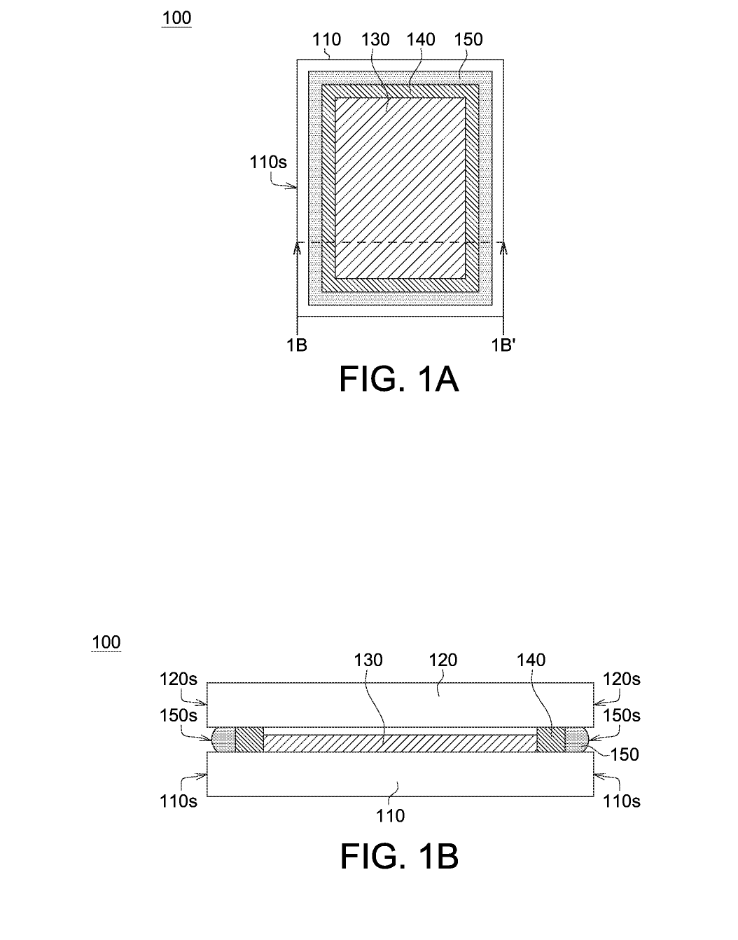

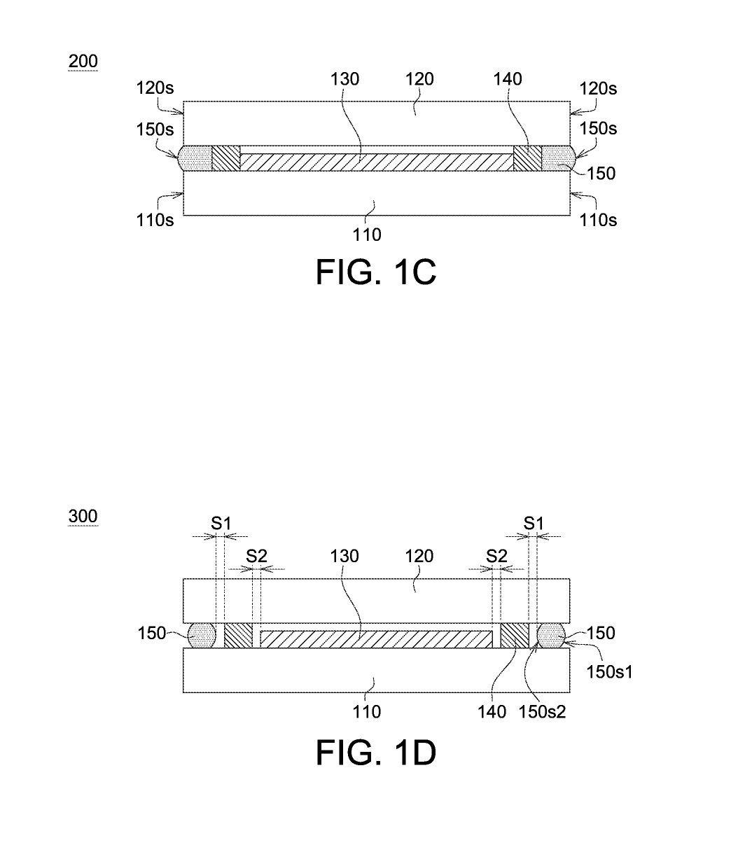

FIG. 1A shows a top view of a display device according to an embodiment of the present disclosure, and FIG. 1B shows a cross-sectional view along the section line 1B-1B′ in FIG. 1A. As shown in FIGS. 1A-1B, the display device 100 includes a first substrate 110, a second substrate 120, a display element 130, an encapsulation layer 140, and an etching stop layer 150. The second substrate 120 is assembled to the first substrate 110. The display element 130 is located between the first substrate 110 and the second substrate 120. The encapsulation layer 140 surrounds the display element 130, and the encapsulation layer 140 contacts the first substrate 110 and the second substrate 120. The etching stop layer 150 surrounds the encapsulation layer 140, and the etching stop layer 150 contacts the first substrate 110 and the second substrate 120. The etching stop layer 150 has at least a sidewall 150s having an arc-shaped protruded surface. In the embodiment, the display element 130 may include, for example, a liquid crystal layer, an organic light emitting diode layer, or an inorganic light emitting diode layer.

In the embodiment, the encapsulation layer 140 surrounds the display element 130 and contacts the first substrate 110 and the second substrate 120, such that the display element 130 can be sealed between the first substrate 110 and the second substrate 120; accordingly, the damage of water and oxygen from external environment can be effectively blocked, and the life of the display device 100 can be further extended. In the embodiment, the encapsulation layer 140 may include, for example, frit, UV curable resin or thermosetting resin. However, the selections of the encapsulation layer 140 may depend on actual needs and are not limited to the above-mentioned examples.

In the embodiment, the etching stop layer 150 surrounds the encapsulation layer 140 and contacts the first substrate 110 and the second substrate 120, such that the encapsulation layer 140 can be sealed between the first substrate 110 and the second substrate 120. Accordingly, the etching stop layer 150 can effectively protect the encapsulation layer 140 from the damage of the chemical etching solution in the manufacturing process, the consistency of the structure of the encapsulation layer 140 as well as the sealing ability of the encapsulation layer 140 regarding resistance to water and oxygen can be maintained, and hence the encapsulation layer 140 can achieve the effect of excellent resistance to water and oxygen, the durability and stability of the display device 100 can be increased, and the life of the display device 100 can be further extended.

As shown in FIGS. 1A-1B, in the embodiment, the etching stop layer 150 directly contacts the encapsulation layer 140. As such, the size of the border area around the display surface can be reduced, and hence the area of the display device 100 is further reduced.

In the present embodiment, as shown in FIG. 1B, the etching stop layer 150 is located between the first substrate 110 and the second substrate 120. That is, the etching stop layer 150 is fully located in a space between the first substrate 110 and the second substrate 120. The etching stop layer 150 includes at least one sidewall 150s having an arc-shaped protruded surface.

In the embodiment, the etching stop layer 150 includes at least two sidewalls 150s each having an arc-shaped protruded surface. The outer edge 110s of the first substrate 110 and the outer edge 120s of the second substrate 120 are substantially aligned with each other and define a boundary of the space wherein the etching stop layer 150 is located. And the arc-shaped protruded surface of the sidewall 150s is located within the space.

In the embodiment, the etching stop layer 150 may include such as a thermoplastic resin, a thermosetting resin, and/or rubber. The thermoplastic resin may be, for example, polyvinyl chloride (PVC) resin, acrylonitrile-butadiene-styrene (ABS) resin, polyethylene (PE) resin, polypropylene (PP) resin, poly(methyl methacrylate) (PMMA) resin, polytetrafluoroethene (PTFE) resin, ethylene tetrafluoroethylene (ETFE) resin, polycarbonate (PC) resin, polymethylpentene (PMP) resin, or any combination thereof. The thermosetting resin may be, for example, paraformaldehyde (PF) resin, epoxide (EP) resin, or a combination thereof. The rubber may be, for example, fluoroelastomer polymer (FPM). In some examples, when the chemical etching solution used in the manufacturing process is a hydrofluoric acid series etching solution for etching glass materials, and the material of the etching stop layer 150 is preferably selected from a material which is not etched by a hydrofluoric acid series etching solution, such as polytetrafluoroethene (PTFE) resin. However, the selections of the etching stop layer 150 may depend on actual needs and are not limited to the above-mentioned example.

In some embodiments, the first substrate 110 and the second substrate 120 are such as glass substrates.

In some embodiments, at least one of the first substrate 110 and the second substrate 120 may be a flexible substrate. In one embodiment, the first substrate 110 is such as a glass substrate, and the second substrate 120 is such as a flexible substrate made of an organic material. In another embodiment, the second substrate 120 is such as a glass substrate, and the first substrate 110 is such as a flexible substrate made of an organic material. In another embodiment, the first substrate 110 and the second substrate 120 are such as flexible substrates.

In some embodiments, at least one of the first substrate 110 and the second substrate 120 includes an anti-etching material; that is, at least one of the first substrate 110 and the second substrate 120 may be an anti-etching substrate. In one embodiment, the first substrate 110 is such as a glass substrate, and the second substrate 120 is an anti-etching substrate. In another embodiment, the second substrate 120 is such as a glass substrate, and the first substrate 110 is an anti-etching substrate. In another embodiment, the first substrate 110 and the second substrate 120 are such as anti-etching substrates.

FIG. 10 shows a cross-sectional view of a display device according to another embodiment of the present disclosure. The elements in the present embodiment sharing similar or the same labels with those in the previous embodiment are similar or the same elements, and the description of which is omitted.

As shown in FIG. 1C, in the embodiment, in the display device 200, the etching stop layer 150 is partially located in a space between the first substrate 110 and the second substrate 120. The outer edge 110s of the first substrate 110 and the outer edge 120s of the second substrate 120 are substantially aligned with each other and define a boundary of the space wherein the etching stop layer 150 is located. And the arc-shaped protruded surface of the sidewall 150s is located outside the space.

FIG. 1D shows a cross-sectional view of a display device according to a further embodiment of the present disclosure. The elements in the present embodiment sharing similar or the same labels with those in the previous embodiments are similar or the same elements, and the description of which is omitted.

In the present embodiment, in the display device 300, the encapsulation layer 140 is such as a frit layer. As shown in FIG. 1D, the etching stop layer 150 and the encapsulation layer 140 may be separated by a spacing S1, and the encapsulation layer 140 and the display element 130 may be separated by a spacing S2 as well. Since a high temperature heating treatment is required in the manufacturing process of the frit layer (encapsulation layer 140), the spacing S1 between the etching stop layer 150 and the encapsulation layer 140 can prevent the damage of the etching stop layer 150 from the high temperature manufacturing process of the frit layer (encapsulation layer 140). Moreover, the spacing S2 between the encapsulation layer 140 and the display element 130 can prevent the damage of the display element 130 from the high temperature manufacturing process of the frit layer (encapsulation layer 140) as well.

In the present embodiment, as shown in FIG. 1D, the two opposite sidewall 150s1 and sidewall 150s2 both have arc-shaped protruded surfaces.

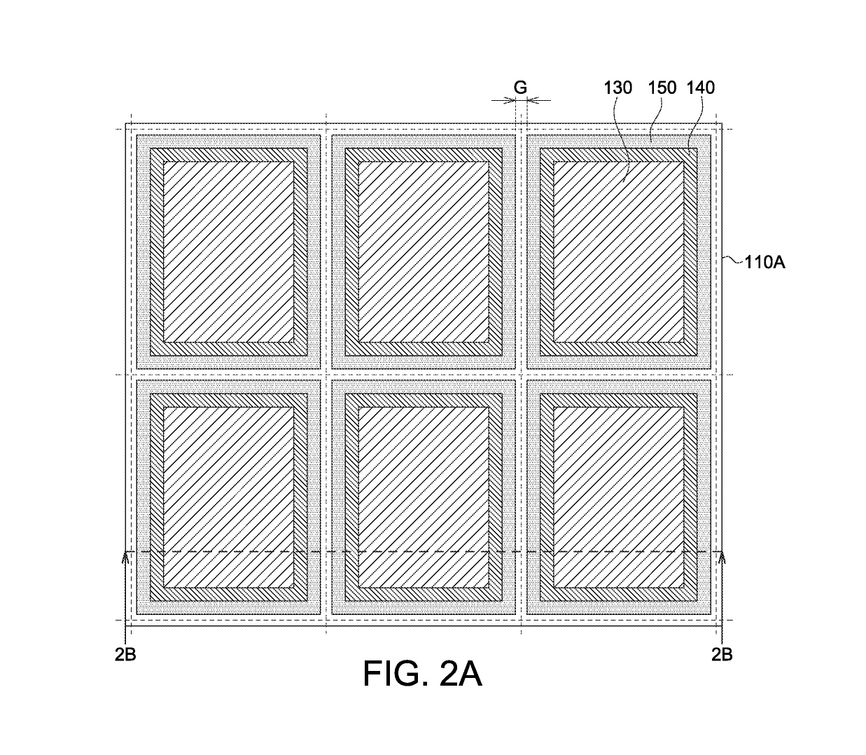

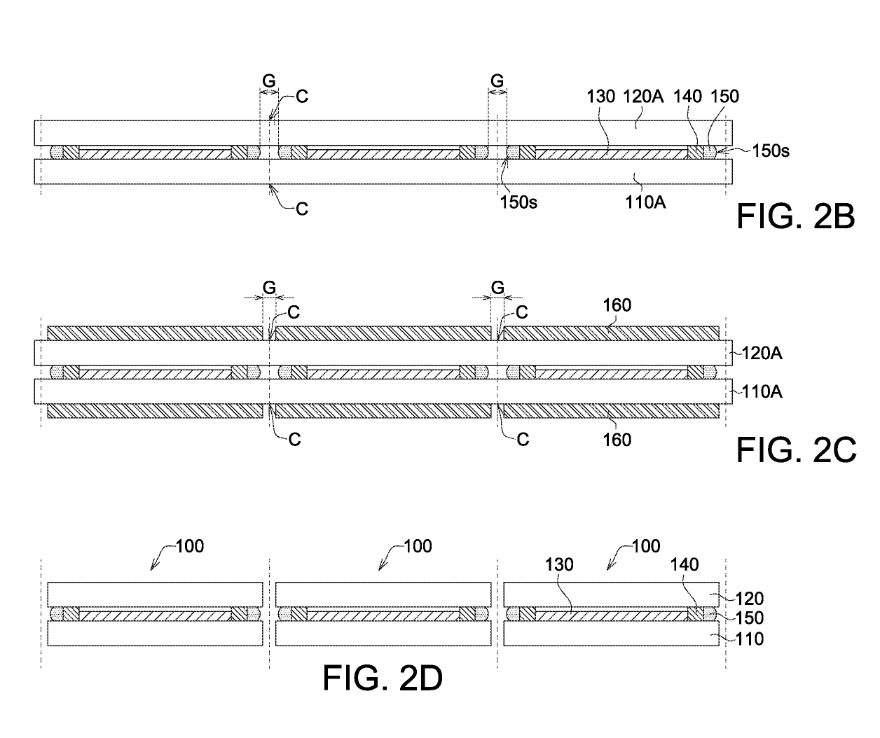

FIGS. 2A-2D illustrate a manufacturing method of a display device according to an embodiment of the present disclosure, wherein FIG. 2A shows a top view, and FIG. 2B shows a cross-sectional view along the section line 2B-2B′ in FIG. 2A. The elements in the present embodiment sharing similar or the same labels with those in the previous embodiments are similar or the same elements, and the description of which is omitted.

Please refer to FIGS. 2A-2B. A first base 110A is provided. The display elements 130 are disposed on the first base 110A. A plurality of the encapsulation layers 140 are disposed on the first base 110A, each of the encapsulation layers 140 correspondingly surrounding each of the display elements 130. A plurality of the etching stop layers 150 are disposed on the first base 110A, wherein each of the etching stop layers 150 correspondingly surrounds each of the encapsulation layers 140, and the etching stop layers 150 are separated from each other by a plurality of gap G, wherein the manufacturing method of disposing the encapsulation layers 140 and the etching stop layers 150 on the first base 110A may be selected from any one of a coating process, a printing process, a dispensing process, or photolithography, according to the properties of the materials. A second base 120A is provided to be assembled to the first base 110A; since the encapsulation layers 140 and the etching stop layers 150 on the first base 110A are pressed by the second base 120A, at least one sidewall 150s of each of the etching stop layers 150 forms an arc-shaped protruded surface. The second base 120A is tightly assembled to the first base 110A via the encapsulation layers 140 and the etching stop layers 150 by a UV irradiation process or a thermal baking process.

Next, as shown in FIGS. 2C-2D, a chemical etching process is performed along the gaps G between the etching stop layers 150 for separating at least one of the first base 110A and the second base 120A, thereby forming a plurality of the display devices 100 separated from each other.

In the display devices manufactured by mechanical cutting processes, micro cracks may be formed around the cutting cross-sectional edges of the substrate surfaces. In contrast, according to the embodiments of the present disclosure, the display devices are manufactured by a chemical etching process along the gaps G between the etching stop layers 150, such that no micro crack would be formed on the surfaces of the substrates, and hence the issues of the structure strength of the display devices being damaged due to micro cracks suffering from applied forces in the subsequent manufacturing processes or uses can be effectively prevented. In addition, the encapsulation layers 140 can be effectively protected by the etching stop layers 150, as such, the encapsulation layer 140 can maintain excellent resistance to water and oxygen, and the durability and stability of the display device can be further increased.

In the present embodiment, the first base 110A and the second base 120A are both glass substrates. As shown in FIG. 2C, prior to the chemical etching process, a plurality of masks 160 are disposed on the first base 110A and the second base 120A to expose the gaps G. The masks 160 are preferably anti-etching masks. The positions and the covering areas of the masks 160 substantially define the predetermined positions and areas of the display devices 100 to be made.

In the embodiment, the chemical etching process may include etching the first base 110A and/or the second base 120A according to the masks 160. For example, a hydrofluoric acid series etching solution may be used as a chemical etching solution, and the first base 110A and/or the second base 120A having glass material are etched along the gaps G exposed between the masks 160.

In the embodiment, prior to the chemical etching process, a mechanical process may be optionally performed along the gaps G to form a plurality of cutting grooves on at least one of the first base 110A and the second base 120A, which are predetermined to be separated. These cutting grooves are merely formed on the surface, where an etching solution is predetermined to apply on, of the first base 110A and/or the second base 120A, and the depths of these cutting grooves are smaller than the thickness of the first base 110A and/or the second base 120A, and thus the cutting grooves do not penetrate through the first base 110A and/or the second base 120A.

In the present embodiment, as shown in FIG. 2C, the first base 110A and the second base 120A are etched along the gaps G. Prior to the etching process, a mechanical process is performed along the gaps G to form cutting grooves at the positions C on the surfaces of the first base 110A and the second base 120A. For example, the cutting grooves are formed by such as cutting the positions C along the middle of the gaps G by a diamond knife or a metal knife. In the present embodiment, the thicknesses of the first base 110A and the second base 120A are about 100-1000 micrometers (μm), and the depths of the cutting grooves are about 10-100 μm, which may vary depending on the thickness of the bases. Next, the chemical etching process is performed at the positions C where the cutting grooves are formed.

The cutting grooves can increase the etching rate; thereby the cutting step by the chemical etching process can be speeded up. In addition, although micro cracks may be formed around the cutting grooves after the cutting grooves are formed by cutting the substrates by a mechanical process, the region having the micro cracks will then be removed along with the removal of portions of the substrates by the chemical etching process. In such case, after the cutting step by the chemical etching process, no micro crack would remain on the substrates of the as-made display devices, and thus the issues of the structure strength of the display devices being damaged due to the existence of micro cracks can be effectively prevented, even when the devices are suffered from bending forces in the subsequent manufacturing processes or uses.

In the present embodiment, in the chemical etching process, the first base 110A and the second base 120A of glass materials are etched by such as a hydrofluoric acid series etching solution for separating the first base 110A and the second base 120A into a plurality of the first substrates 110 and a plurality of the second substrates 120. After the masks 160 are removed, the display devices 100 separated from each other are formed. As shown in FIG. 2D, each of the display devices includes a first substrate 110, a second substrate 120, a display element 130, an encapsulation layer 140, and an etching stop layer 150.

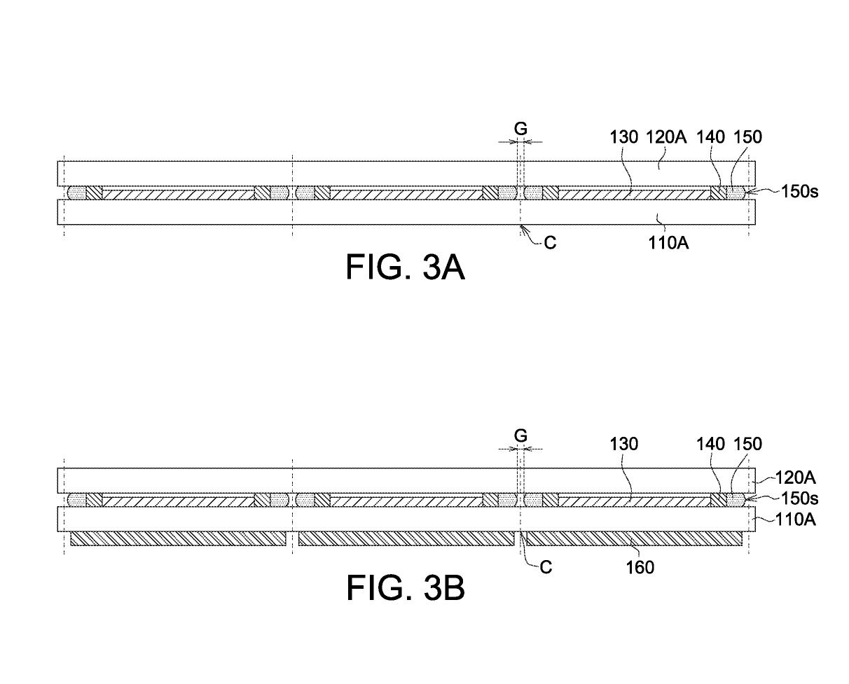

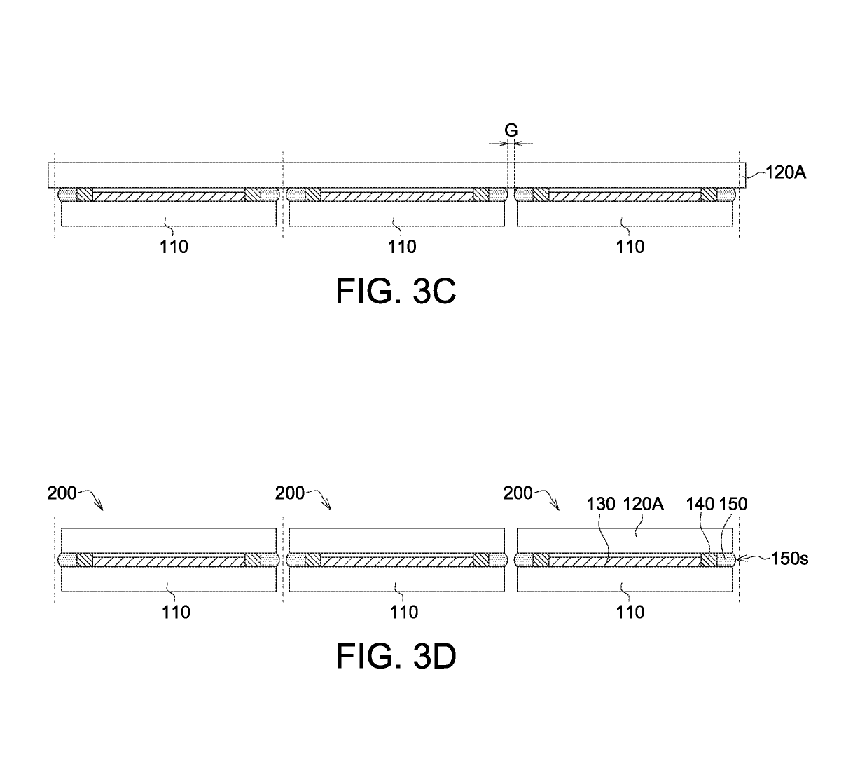

FIGS. 3A-3D illustrate a manufacturing method of a display device according to another embodiment of the present disclosure. The elements in the present embodiment sharing similar or the same labels with those in the previous embodiments are similar or the same elements, and the description of which is omitted.

As shown in FIG. 3A, the present embodiment is similar to the embodiment as shown in FIGS. 2A-2B except that the second base 120A is an anti-etching substrate. The first base 110A is provided, the display elements 130 are disposed, the encapsulation layers 140 and the etching stop layers 150 are formed on the first base 110A, and the second base 120A is provided to be assembled to the first base 110A. Since the encapsulation layers 140 and the etching stop layers 150 on the first base 110A are pressed by the second base 120A, at least one sidewall 150s of each of the etching stop layers 150 forms an arc-shaped protruded surface. The second base 120A is tightly assembled to the first base 110A via the encapsulation layers 140 and the etching stop layers 150 by a UV irradiation process or a thermal baking process.

Next, as shown in FIGS. 3B-3D, the chemical etching process is performed along the gaps G between the etching stop layers 150 for separating at least one of the first base 110A and the second base 120A, thereby forming a plurality of the display devices 200.

In the present embodiment, the first base 110A is such as a glass substrate, and the second base 120A is an anti-etching substrate. Since the second base 120A is anti-etching, the second base 120A would not be damaged by the etching solution in the subsequent chemical etching process.

As shown in FIG. 3B, prior to the chemical etching process, a plurality of masks 160 are disposed on the first base 110A to expose the gaps G. The positions and the covering areas of the masks 160 substantially define the predetermined positions and areas of the display devices 200 to be made.

In the present embodiment, prior to the chemical etching process, a mechanical process may be optionally performed along the gaps G to form a plurality of cutting grooves on the first base 110A, which is predetermined to be separated. That is, these cutting grooves are formed on the surface, where an etching solution is predetermined to apply on, of the first base 110A. For example, the cutting grooves are formed by such as cutting the positions C along the middle of the gaps G by a diamond knife or a metal knife, and the depths of these cutting grooves are smaller than the thickness of the first base 110A. Next, the chemical etching process is performed at the positions C where the cutting grooves are formed.

In the present embodiment, as shown in FIG. 3C, the chemical etching process may include etching the first base 110A according to the masks 160. For example, a hydrofluoric acid series etching solution may be used as a chemical etching solution, and the first base 110A having glass material is etched along the gaps G exposed between the masks 160 for separating the first base 110A into a plurality of the first substrates 110.

Next, as shown in FIG. 3C, the masks 160 are removed.

Next, a mechanical process is performed along the gaps G to separate the second base 120A. For example, the second base 120A is cut along the gaps G by a diamond knife or a metal knife for separating the second base 120A into a plurality of the second substrates 120. As such, the display devices 200 as shown in FIG. 3D are formed.

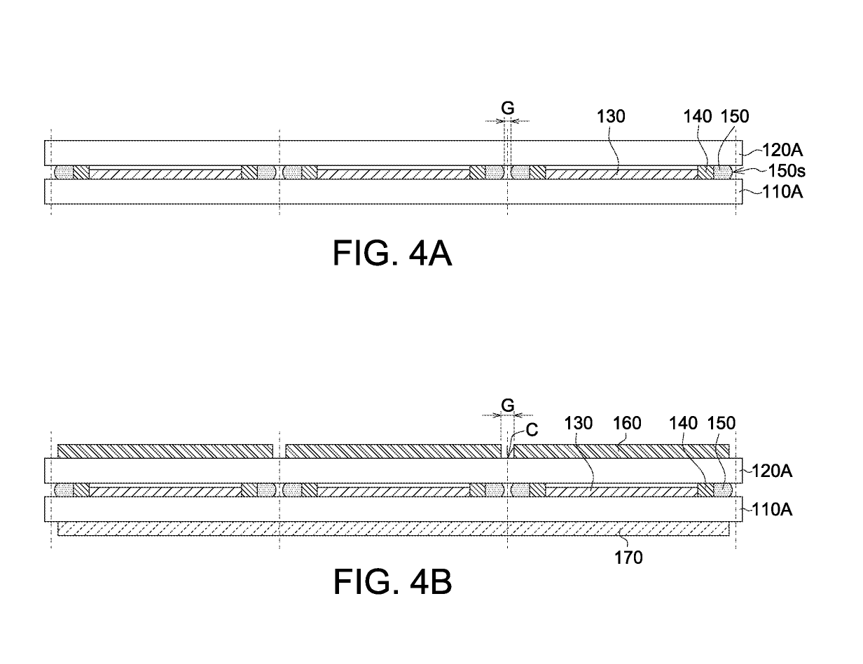

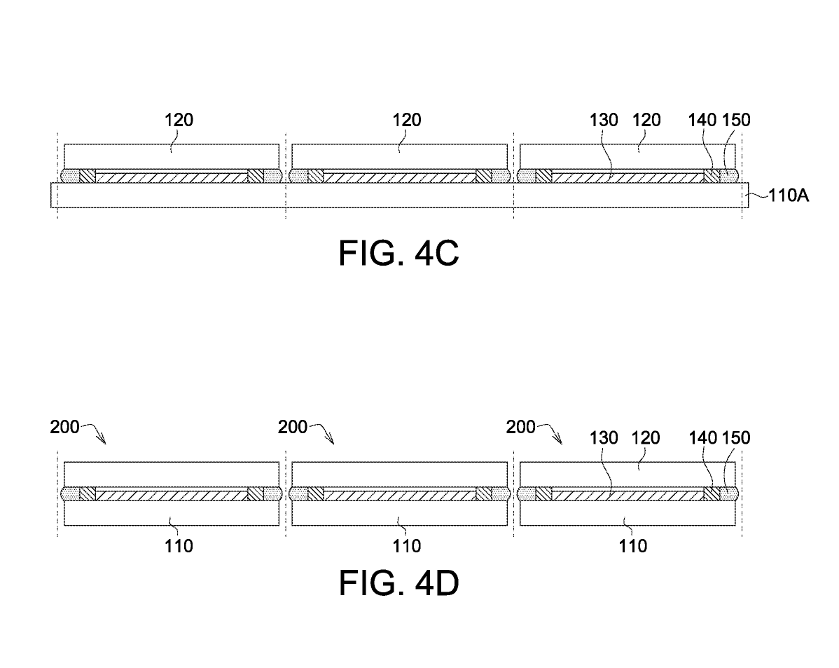

FIGS. 4A-4D illustrate a manufacturing method of a display device according to a further embodiment of the present disclosure. The elements in the present embodiment sharing similar or the same labels with those in the previous embodiments are similar or the same elements, and the description of which is omitted.

As shown in FIG. 4A, the present embodiment is similar to the previous embodiment except that the first base 110A is a flexible substrate. The first base 110A is provided, the display elements 130 are disposed, the encapsulation layers 140 and the etching stop layers 150 are formed on the first base 110A, and the second base 120A is provided to be assembled to the first base 110A. Since the encapsulation layers 140 and the etching stop layers 150 on the first base 110A are pressed by the second base 120A, at least one sidewall 150s of each of the etching stop layers 150 forms an arc-shaped protruded surface. The second base 120A is tightly assembled to the first base 110A via the encapsulation layers 140 and the etching stop layers 150 by a UV irradiation process or a thermal baking process.

Next, as shown in FIGS. 4B-4D, the chemical etching process is performed along the gaps G between the etching stop layers 150 for separating at least one of the first base 110A and the second base 120A, thereby forming a plurality of the display devices 200.

In the present embodiment, the first base 110A is a flexible substrate. In the embodiment, the flexible substrate may have an organic material or an inorganic material. In the present embodiment, the second base 120A is such as a glass substrate.

As shown in FIG. 4B, an anti-etching material layer 170 is disposed covering the first base 110A for protecting the first base 110A from the damage by the subsequent chemical etching process.

As shown in FIG. 4B, prior to the chemical etching process, a plurality of masks 160 are disposed on the second base 120A to expose the gaps G. The positions and the covering areas of the masks 160 substantially define the predetermined positions and areas of the display devices 200 to be made.

In the present embodiment, prior to the chemical etching process, a mechanical process may be optionally performed along the gaps G to form a plurality of cutting grooves on the second base 120A, which is predetermined to be separated. That is, these cutting grooves are formed on the surface, where an etching solution is predetermined to apply on, of the second base 120A. For example, the cutting grooves are formed by such as cutting the positions C along the middle of the gaps G by a diamond knife or a metal knife, and the depths of these cutting grooves are smaller than the thickness of the second base 120A. Next, the chemical etching process is performed at the positions C where the cutting grooves are formed.

In the present embodiment, as shown in FIG. 4C, the chemical etching process may include etching the first base 110A according to the masks 160. For example, a hydrofluoric acid series etching solution may be used as a chemical etching solution, and the second base 120A having glass material is etched along the gaps G exposed between the masks 160 for separating the second base 120A into a plurality of the second substrates 120.

In the present embodiment, as shown in FIG. 4C, after the chemical etching process, the anti-etching material layer 170 and the masks 160 are removed.

Next, a mechanical process is performed along the gaps G to separate the first base 110A. For example, the first base 110A is cut along the gaps G by a diamond knife or a metal knife for separating the first base 110A into a plurality of the first substrates 110. As such, the display devices 200 as shown in FIG. 4D are formed.

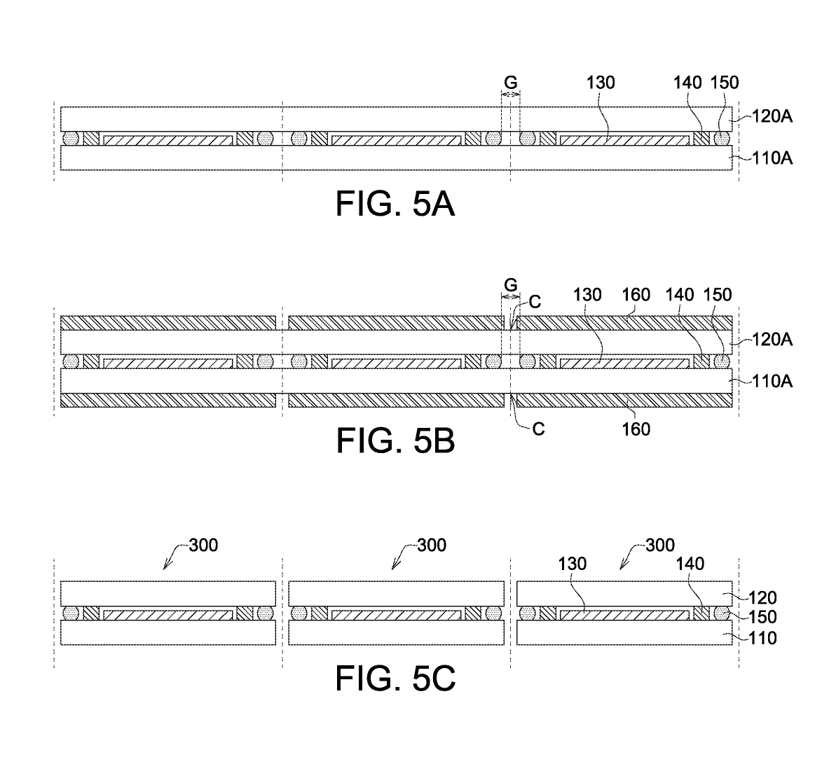

FIGS. 5A-5C illustrate a manufacturing method of a display device according to a still further embodiment of the present disclosure. The elements in the present embodiment sharing similar or the same labels with those in the previous embodiments are similar or the same elements, and the description of which is omitted.

As shown in FIG. 5A, the present embodiment is similar to the previous embodiment except that the encapsulation layer 140 and the etching stop layer 150 is separated by a spacing. The first base 110A is provided, the display elements 130 are disposed, the encapsulation layers 140 and the etching stop layers 150 are formed on the first base 110A, and the second base 120A is provided to be assembled to the first base 110A.

Next, as shown in FIGS. 5B-5C, the chemical etching process is performed along the gaps G between the etching stop layers 150 for separating at least one of the first base 110A and the second base 120A, thereby forming a plurality of the display devices 300.

In the present embodiment, the encapsulation layer 140 is a frit layer, each of the etching stop layers 150 and each of the corresponding encapsulation layers 140 are separated by a spacing S1, and each of the encapsulation layers 140 and each of the corresponding display element 130 may also be separated by a spacing S2.

In the present embodiment, after the first base 120A is assembled to the first base 110A, the encapsulation is melted and then cooled down, such that the second bass 120A is adhered to and tightly assembled to the first base 110A.

In the present embodiment, the first base 110A and the second base 120A are both glass substrates. As shown in FIG. 5B, prior to the chemical etching process, a plurality of masks 160 are disposed on the first base 110A and the second base 120A to expose the gaps G. The positions and the covering areas of the masks 160 substantially define the predetermined positions and areas of the display devices 100 to be made.

In the embodiment, prior to the chemical etching process, a mechanical process may be optionally performed along the gaps G to form a plurality of cutting grooves on the first base 110A and the second base 120A, which are predetermined to be separated. For example, the cutting grooves are formed by such as cutting the positions C along the middle of the gaps G by a diamond knife or a metal knife. These cutting grooves are merely formed on the surface, where an etching solution is predetermined to apply on, of the first base 110A and the second base 120A, and the depths of these cutting grooves are smaller than the thicknesses of the first base 110A and the second base 120A.

In the present embodiment, in the chemical etching process, the first base 110A and the second base 120A of glass materials are etched by such as a hydrofluoric acid series etching solution for separating the first base 110A and the second base 120A into a plurality of the first substrates 110 and a plurality of the second substrates 120. After the masks 160 are removed, the display devices 300 are formed. As shown in FIG. 5C, each of the display devices includes a first substrate 110, a second substrate 120, a display element 130, an encapsulation layer 140, and an etching stop layer 150.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A display device, comprising:
a first substrate;
a second substrate;
a display element located between the first substrate and the second substrate;
an encapsulation layer surrounding the display element and in contact with the first substrate and the second substrate; and
an etching stop layer surrounding the encapsulation layer and in contact with the first substrate and the second substrate.

2. The display device according to claim 1, wherein the etching stop layer is disposed in a space between the first substrate and the second substrate.

3. The display device according to claim 2, wherein the etching stop layer includes at least one sidewall having an arc-shaped protruded surface.

4. The display device according to claim 3, wherein an outer edge of the first substrate and an outer edge of the second substrate define a boundary of the space, and the arc-shaped protruded surface is located within the space.

5. The display device according to claim 3, wherein an outer edge of the first substrate and an outer edge of the second substrate define a boundary of the space, and the arc-shaped protruded surface is located outside the space.

6. The display device according to claim 1, wherein the etching stop layer includes at least two sidewalls each having an arc-shaped protruded surface.

7. The display device according to claim 1, wherein the etching stop layer contacts the encapsulation layer.

8. The display device according to claim 1, wherein the etching stop layer and the encapsulation layer are separated by a first spacing.

9. The display device according to claim 1, wherein the encapsulation layer and the display element are separated by a second spacing.

10. The display device according to claim 1, wherein the first substrate is a flexible substrate.

11. The display device according to claim 1, wherein the first substrate is an anti-etching substrate.

12. The display device according to claim 1, wherein the display element is a liquid crystal layer, an organic light emitting diode layer, or an inorganic light emitting diode layer.

13. The display device according to claim 1, wherein the etching stop layer is formed of a thermoplastic resin.

14. The display device according to claim 13, wherein the thermoplastic resin comprises polyvinyl chloride (PVC) resin, acrylonitrile-butadiene-styrene (ABS) resin, polyethylene (PE) resin, polypropylene (PP) resin, poly(methyl methacrylate) (PMMA) resin, polytetrafluoroethene (PTFE) resin, ethylene tetrafluoroethylene (ETFE) resin, polycarbonate (PC) resin, polymethylpentene (PMP) resin, or any combination thereof.

15. The display device according to claim 1, wherein the etching stop layer is formed of a thermosetting resin.

16. The display device according to claim 15, wherein the thermosetting resin comprises paraformaldehyde (PF) resin, epoxide (EP) resin, or a combination thereof.

17. A manufacturing method of a display device, comprising:
providing a first base;
disposing a plurality of display elements on the first base;
disposing a plurality of encapsulation layers on the first base, each of the encapsulation layers surrounding each of the display elements,
disposing a plurality of etching stop layers on the first base, wherein each of the etching stop layers surrounds each of the encapsulation layers, and the etching stop layers are separated from each other by a plurality of gaps;
providing a second base to be assembled to the first base, wherein the encapsulation layers and the etching stop layers contact the first base and the second base; and
performing a chemical etching process on the first base and the second base along the gaps between the etching stop layers for forming a plurality of the display devices separated from each other, wherein each of the display devices comprises one of the display elements, one of the encapsulation layers, and one of the etching stop layers.

18. The manufacturing method according to claim 17, wherein prior to performing the chemical etching process, the manufacturing method further comprises forming a cutting groove along the gaps by a mechanical process.

19. The manufacturing method according to claim 17, wherein prior to performing the chemical etching process, the manufacturing method further comprises disposing a plurality of masks on the first base and the second base to expose the gaps.

20. The manufacturing method according to claim 17, wherein a hydrofluoric acid series etching solution is used as a chemical etching solution during the chemical etching process.
